(19) United States
(12) Patent Application Publication
(10) Pub. No.: US 2004/0126924 A1
(43) Pub. Date: Jul. 1, 2004

(54) Wafer center calibrator

(75) Inventor: Johnny Chen, Hsin-Chu (TW)

Correspondence Address: INTELLECTUAL PROPERTY SOLUTIONS, INCORPORATED, 5717 COLFAX AVENUE, ALEXANDRIA, VA, 22311, US

(73) Assignee: WINBOND ELECTRONICS CORPORATION, Hsinchu (TW)

(21) Appl. No.: 10/331,634

(22) Filed: Dec. 31, 2002

(51) Int. Cl. H01L 21/00

(52) U.S. Cl. 438/80

(57) ABSTRACT

The present invention provides a wafer center calibrator to improve the uniformity of the etching, or deposition on a wafer, which is spoiled by the poor assembly of the focus ring with the wafer loader. Thus comprising of a main part, at least one arc part, a handle or any other means by which the calibrator is rotated a round. To use the wafer center calibrator provided by the present invention, at least one arc part is placed into the ring-shaped gap formed between the focus ring and the wafer loader, then the wafer center calibrator is rotated around by a user or any other means. At least one arc part rubs against the focus ring and pushes through where the ring-shaped gap is narrower. Meanwhile, the calibration is rapid and simple, therefore the improvement of the uniformity of the etching or deposition on the wafer can be made in an economical and effective way.

### BACKGROUND OF THE INVENTION

1. Field of the Invention

This present invention relates to a wafer center calibrator, and more particularly to a wafer center calibrator for wafer depositing or etching equipment.

2. Description of the Prior Art

With the development of the technology, the research and manufacture of semiconductor devices are going into the nano-meter age. The size thereof, gets smaller and smaller, and the function thereof, is more and more powerful. With the decreasing in device size, a semiconductor device will be more sensitive with a slight change during manufacturing, and thus the requirement during the manufacture will be more and more critical. Some of the original allowable inaccuracies may cause defects in a device while decreasing the device size, thus becoming unallowable. Therefore, in order to improve the performance of the devices, when the device size is decreased, the conditions in manufacturing the devices must be more careful. The above-mentioned conditions comprise the reaction temperature, the cooling performance of a wafer, the pressure in a chamber, the uniformity of the reaction on a wafer, and so on.

Generally, a semiconductor manufacture comprises many steps, such as deposition, photolithography, etching, and other processes. FIG. 1 shows a diagram of a semiconductor manufacture in the prior art. A wafer, not shown in the figure, is taken from the load lock 12, by a robot arm 14. A cleaning process of the wafer is performed in the transfer chamber 16, for removing the oxide, or other residues, on the surface of the wafer. Next, the wafer is transferred into the process chamber 18, by the robot arm 14 for semiconductor manufacturing. The reaction performed on the wafer in the process chamber 18 may be a deposition, etching, or other process. For instance, referring to FIG. 2 showing a lateral view of a plasma etching chamber, a wafer 20 is disposed onto a baffle plate 22. The cathode 24 is under the baffle plate 22. After introducing the reaction gas 26 into the chamber, the reaction gas 26 is reacted with the electric field between the cathode 24 and the anode 28, ionized, and transferred into plasma. The positive ions of the plasma will move forward to the cathode 24, and thus the etching reaction is performed on the wafer 20 on the baffle plate 22. FIG. 3 shows a lateral view of the wafer load portion in a plasma etching chamber. A wafer (not shown in the figure) is disposed onto the electrostatic chuck (ESC) 30. The electrostatic chuck 30 is a disc-shaped support for loading and adsorbing the wafer. A focus ring 32 is around said electrostatic chuck 30. The lateral view of the focus ring 32 is a L-shaped form. The diameter of the focus ring is a little larger than the diameter of the electrostatic chuck 30. The thickness H2 of the bottom portion of the L-shaped focus ring 32 is a little shorter than the thickness of the electrostatic chuck 30, as shown in FIG. 3. Thus, during the etching process, the wafer is limited inside the ring wall of the focus ring 32 and almost focused to the center of the electrostatic chuck 30. The above-mentioned design is convenient for the robot arm 14 to take and dispose the wafer, and the uniformity of the reaction on the wafer can be improved. Generally, the focus ring 32 is disposed onto the electrostatic chuck 30 by an operator, so that it is hard to make the relative position of the focus ring 32 and the electrostatic chuck 30 in the ideal homocentric form. FIG. 4 shows a lateral view of a chamber during an etching process. Referring to FIG. 4, because the relative position of the focus ring 32 and the electrostatic chuck 30 is not disposed in the ideal homocentric form, the distance A at one portion of the gap between the focus ring 32 and the electrostatic chuck 30 is not equal to that of distance B at another portion of the gap, between the focus ring 32 and the electrostatic chuck 30. Thus, the distances between the edge of the wafer 20 and the focus ring 32 are not uniform. The etching rate and the performance of the etching process are affected by the plasma concentration, wherein the plasma concentration is relative to the distribution of the electric field in the chamber. Therefore, the etched performances of the edge portions of the wafer 20 in FIG. 4 are different because of the various plasma concentrations. In other words, referring to FIG. 4, distance A is longer than distance B, and thus the etching rate at the edge portion C of the wafer 20 is faster than the etching rate at the edge portion D of the wafer 20. Besides, because of the inaccuracies of the fabrication by mental reason vary case-by-case. Therefore, after each resetting of the focus ring 32 for fabrication or maintenance, the uniformities of the reaction on the wafers are different. Additionally, in a general deposition process, such as a plasma-enhanced chemical vapor deposition (PECVD) process, the uniformity of the reaction on a wafer is still affected by the distribution of the plasma in a chamber. In order to prevent the above-mentioned defects, one method in the prior art comprises putting one wafer into the chamber for testing after each resetting of the focus ring or the electrostatic chuck, performing a reaction onto the testing wafer, measuring the reaction result of the wafer, and adjusting the relative position of the focus ring and the electrostatic chuck with the testing result of the testing wafer.

However, the above-mentioned method is very complex for repeating the steps of measurement and adjustment. Besides, even after the above-mentioned calibration, the uniformity of the reaction on a wafer is not good enough, especially while decreasing the device size. Hence, it is an important object of developing a method for efficiently calibrating a wafer center position in a chamber to optimize the uniformity of the reaction on the wafer.

### SUMMARY OF THE INVENTION

In accordance with the present invention, a wafer center calibrator is provided for calibrating the relative position of the focus ring and the electrostatic chuck in a chamber.

It is another object of this invention to provide a wafer center calibrator for improving the reaction uniformity on a wafer in a chamber.

Still another object of this invention is to provide a simple and efficient wafer center calibrator, so that the calibrating process for the relative position of the electrostatic chuck and the focus ring can be simplified.

In accordance with the above-mentioned objects, the invention provides a wafer center calibrator. The above-mentioned wafer center calibrator at least comprises a curve-shaped art part. The curvature radius of the art part is equal to the curvature radius of the electrostatic chuck and the focus ring. The thickness and the width of the art part are relative to the ring-like gap between the electrostatic chuck and the focus ring. When calibrating with the wafer center calibrator, the wafer center calibrator is put on the electrostatic chuck and the focus ring, and the art part is disposed into the ring-like gap between the electrostatic chuck and the focus ring. With rotating the art part in the ring-like gap, the distance between the electrostatic chuck and the focus ring becomes uniform everywhere by friction, touch, or pushing between the art part, the electrostatic chuck and the focus ring. Thus, the uniformity of the reaction on a wafer onto the focus ring can be efficiently improved. Moreover, the wafer center calibrator of this invention can be simple and fast employed for calibrating the relative position of the electrostatic chuck and the focus ring. That is, this invention discloses a way for efficiently and economically preventing the uniformity problem of the reaction on a wafer cause of mental reason in the prior art.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows a diagram of a semiconductor manufacture in the prior art;

FIG. 2 shows a lateral view of a plasma etching chamber;

FIG. 3 shows a lateral view of the wafer load portion in a plasma etching chamber;

FIG. 4 shows a lateral view of the chamber during an etching process;

FIG. 5 shows a lateral view of the wafer center calibrator of this invention;

FIG. 6 shows a top-view of the wafer center calibrator of this invention;

FIG. 7 shows a bottom-view of the wafer center calibrator of this invention;

FIG. 8A to FIG. 8C show the diagrams of the ring-like gap between the focus ring and the electrostatic chuck;

FIG. 9A and FIG. 9B show the diagrams of a usual etching process; and

FIG. 10 shows the results of the wafers after an etching process, wherein the wafers are calibrated by the wafer center calibrator according to this present invention.

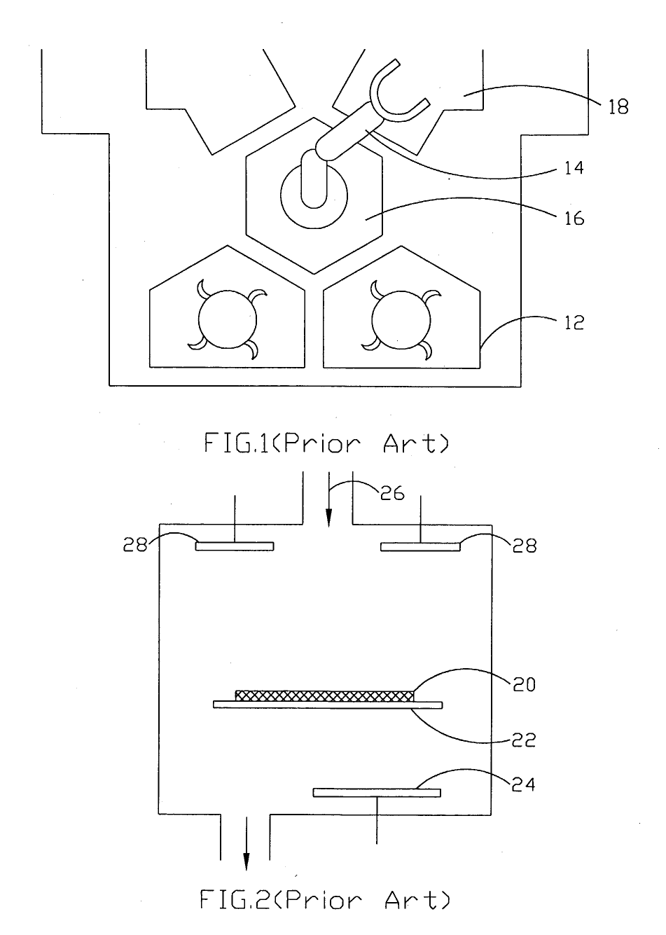

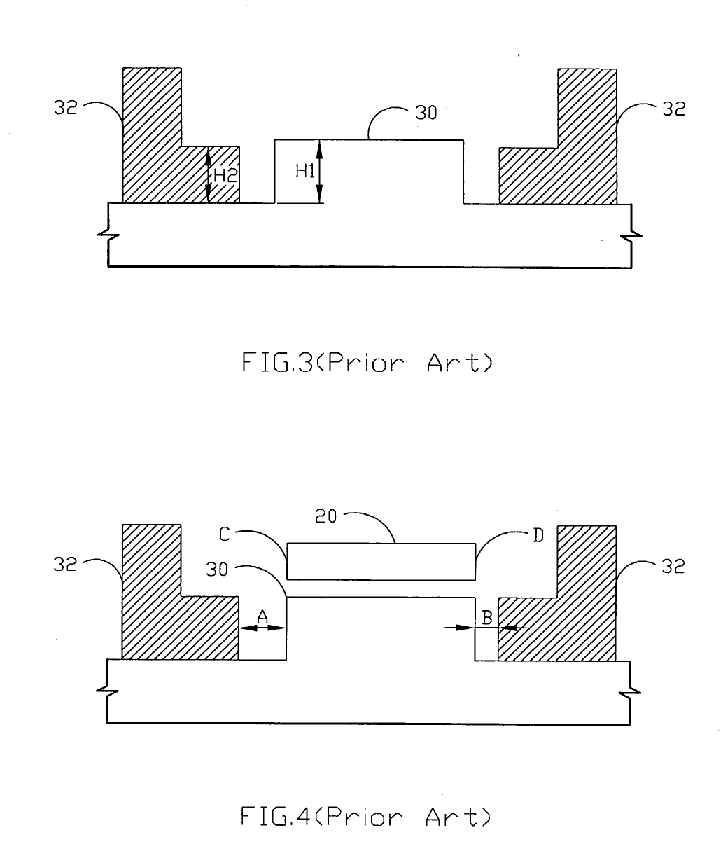

### DESCRIPTION OF THE PREFERRED EMBODIMENTS

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

Then, the components of the devices in this application are not shown to scale. Some dimensions are exaggerated to the related components to provide a more clear description and comprehension of the present invention.

The wafer center calibrator according to this invention is employed for calibrating the fabricating inaccuracy of the focus ring in an etching chamber or in a depositing chamber. The wafer center calibrator of this invention comprises a curve-shaped art part. The curvature radius of the art part is equal to the curvature radius of the electrostatic chuck and the focus ring. When calibrating with the wafer center calibrator, the wafer center calibrator is put on the electrostatic chuck and the focus ring, and the art part is disposed into the ring-like gap between the electrostatic chuck and the focus ring. With rotating the art part in the ring-like gap, the distance between the electrostatic chuck and the focus ring becomes uniform everywhere. Thus, the uniformity of the reaction on a wafer onto the focus ring can be efficiently improved.

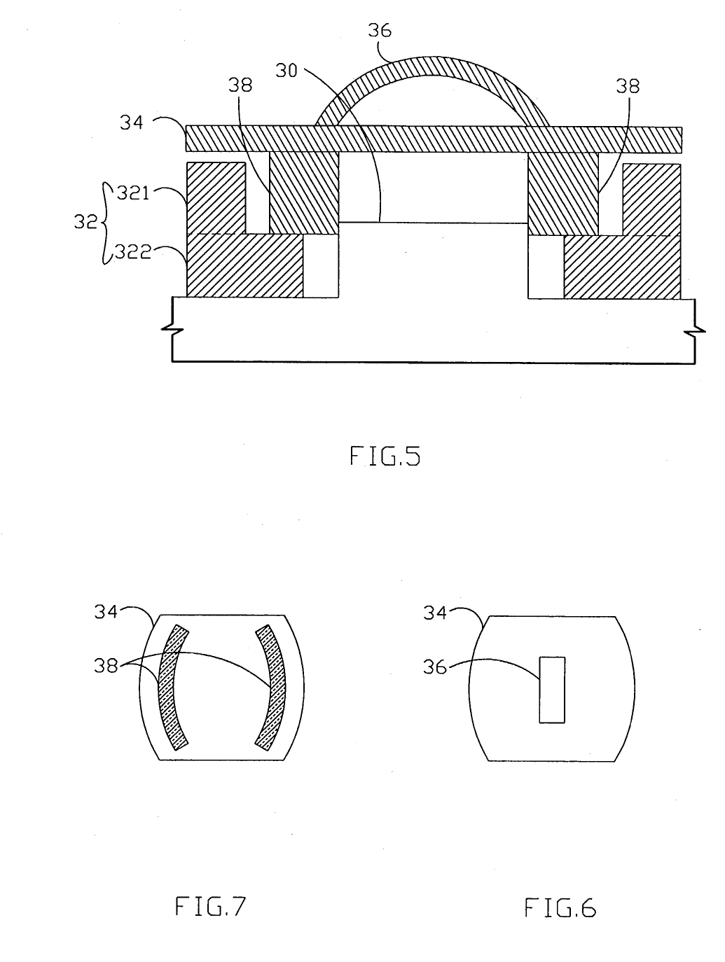

One preferred embodiment of this invention is a wafer center calibrator as shown in FIG. 5 to FIG. 7. FIG. 5 shows a lateral view of the wafer center calibrator. FIG. 6 shows a top-view of the wafer center calibrator. FIG. 7 shows a bottom-view of the wafer center calibrator. The structure of the wafer center calibrator of this embodiment is like a pot-cover-shape. The wafer center calibrator comprises a main part 34, a handle 36, and two art parts 38. The main part 34 is formed like a turtleback-shape, and employed for connecting the handle 36 and the art parts 38. The above-mentioned turtleback-shaped comprises one pair of parallel side portions, and one pair of curve side portions. The curvature radius of the curve side portions is equal to the curvature radius of the art parts 38. Referring to FIG. 7, the art parts 38 are individually disposed along the curve side portions. The art parts 38 and the handle 36 are individually disposed at the opposite sides of the main part 34. Referring to FIG. 5, the focus rings 32 are on the electrostatic chuck 30. The cross-section of the focus ring 32 is L-shaped, wherein the bottom portion of the L-shaped focus ring 32 is the second ring wall 322, and the upper portion of the L-shaped focus ring 32 is the first ring wall 321. According to this embodiment, the internal diameter of the second ring wall 322 of the focus ring 32 is longer than the diameter of the electrostatic chuck 30, and the thickness of the second ring wall 322 is a little smaller than the thickness of the electrostatic chuck 30 for preventing friction between the second ring wall 322 and a wafer. Thus, a ring-like gap is formed inside the first ring wall 321, the second ring wall 322, and the electrostatic chuck 30. When using the wafer center calibrator, the wafer center calibrator is put on the electrostatic chuck 30 and the focus ring 32, and the art parts 38 are into the ring-like gap, inside the electrostatic chuck 30, the first ring wall 321, and the second ring wall 322. The curvature radius of the art parts 38 is suitable to the curvature radius of the curvature radius of the ring-like gap. When rotating the wafer center calibrator, the art parts 38 are moved along the ring-like gap between the electrostatic chuck 30 and the focus ring 32. Because the width of the art parts 38 are designed for the ideal gap between the electrostatic chuck 30 and the focus ring 32, after rotating the calibrator, the gap between the electrostatic chuck 30 and the focus ring 32 will become uniform everywhere. When the art parts 38 are rotated to a narrow portion of the gap, the first ring wall 321 of the focus ring 32 is pushed for passing the art parts 38. While rotating the calibrator, the gap between the electrostatic chuck 30 and the focus ring 32 can be uniform everywhere by the friction, touch, or the like interaction between the electrostatic chuck 30 and the art parts 38, or between the first ring wall 321 and the art parts 38. Therefore, the distance in the ring-like gap between the electrostatic chuck 30 and the focus ring 32 can be more uniform everywhere by design of this embodiment, and thus the reaction of the wafer in the chamber with the above-mentioned focus ring 32 and electrostatic chuck 30 becomes more average.

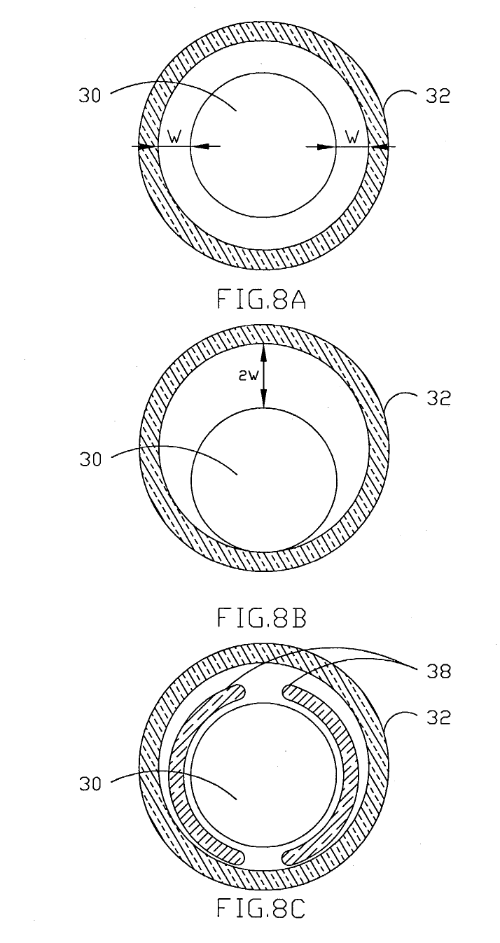

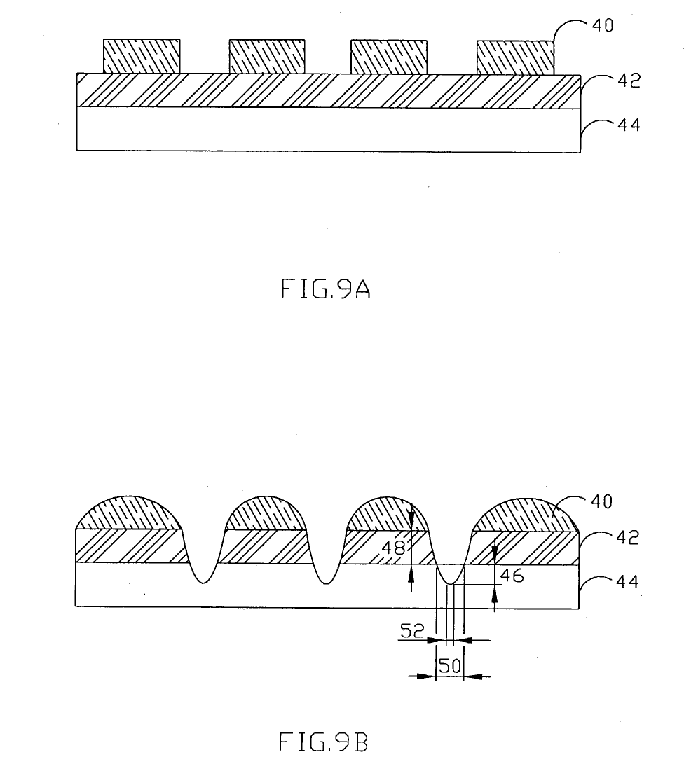

In order to activate the above-mentioned wafer center calibrator, some reference of the art parts 38 in one case of this embodiment is described as following. FIG. 8A shows a diagram of the ideal ring-like gap between the electrostatic chuck 30 and the focus ring 32. Referring to FIG. 8A, the distance between the electrostatic chuck 30 and the first ring wall 321 of the focus ring 32 is W. FIG. 8B shows an extreme relationship of the electrostatic chuck 30 and the focus ring 32. Referring to FIG. 8B, the focus ring 32 is completely diverged from the center the electrostatic chuck 30, and thus one portion of the focus ring 32 touches the electrostatic chuck 30 directly. The maximum distance between the electrostatic chuck 30 and the focus ring 32 is 2W. FIG. 8C shows the relative position of the electrostatic chuck 30 and the focus ring 32 in a usual case. It can be noted in FIG. 8C that the width of the art part 38 is about W. For instance, the width of the art part 38 may be 2.5 cm. If the width of the art part 38 is too large, the art part 38 cannot be put into the ring-like gap between the electrostatic chuck 30 and the focus ring 32. If the width of the art part 38 is too narrow, the calibration efficiency is not good enough, and the focus ring 32 may be still diverge from the center the electrostatic chuck 30 after the calibration of this embodiment. Moreover, even the wafer center calibrator of this embodiment comprises one pair of art parts 38; the calibrator in other cases may comprise only one curve art part. In order to support the wafer center calibrator and rotate the wafer center calibrator stably, the length of the arc in the art part is larger than one half of the circumference of the ideal ring-like gap. According to this embodiment, the gap between the electrostatic chuck 30 and the focus ring 32 can be calibrated by the friction and pushing between the art parts 38 and the ring wall 321. Therefore, if the art part 38 is longer, the calibration efficiency is better. However, if the length of the art part 38 is too long, the art part 38 is hard to be put into the above-mentioned ring-like gap. That is, in order to put the art part 38 into the gap, the relative position of the focus ring 32 has to be adjusted for closing the ideal gap before putting the art part 38. Hence, in this embodiment, the sum of the arc length of the art parts 38 is larger than one half circumference of the ideal ring-like gap. Additionally, there is no special limitation on the shape or the thickness of the main part, the formation of the handle, or the rotation way of the wafer center calibrator. But, the thickness of the art part of the wafer center calibrator must be larger than the thickness of the first ring wall 321 of the focus ring 32 for the rotation of the wafer center calibrator. In one case, the thickness of the first ring wall is about 2 cm. The thickness of the first ring wall 321 means the thickness from the bottom portion contacted with the art part 38 to the top of the first ring wall 321. In one case of this embodiment, the wafer center calibrator is made of engineering plastics. In other cases, the wafer center calibrator can also be constructed with other solid materials, wherein the materials are not easily etched. It also should be noted that some materials, such as Teflon, will easily produce small particles by friction, and the chamber will become polluted by the small particles during the calibration process. Thus, the above-mentioned materials are not suitable for the wafer center calibrator of this embodiment.

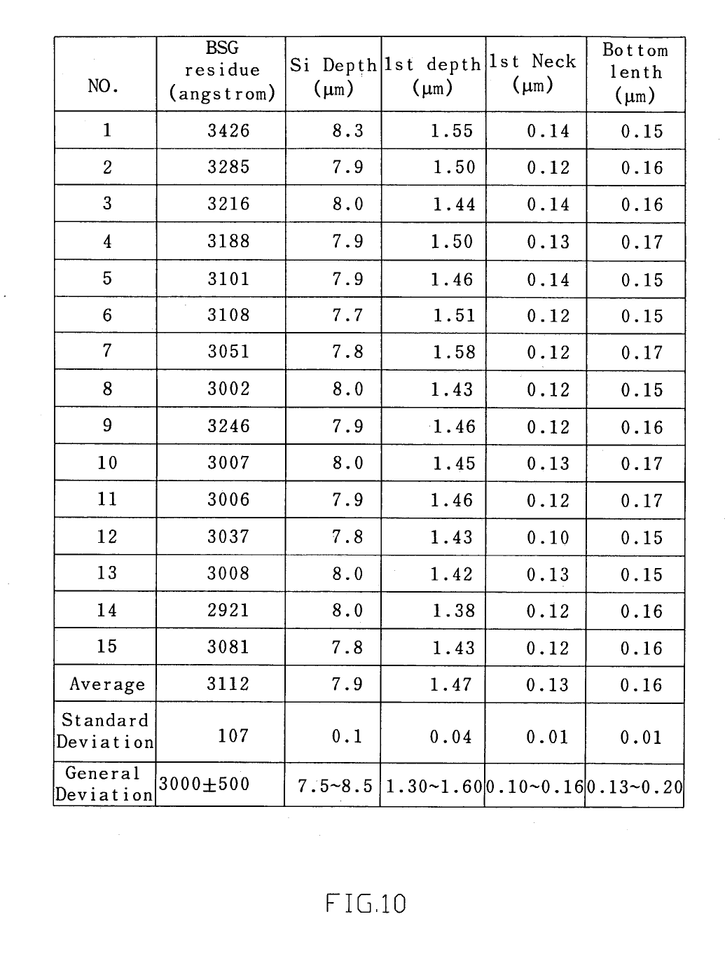

FIGS. 9A and 9B shows the diagrams of a usual etching process. FIG. 9A shows a wafer before the etching process. Referring to FIG. 9A, the layer 40 may be made of Borosilicate Glass (BSG), and employed as the photoresist layer during the etching process. The layer 42 is the etching target of the etching process. The layer 42 may be constructed of SiN. The substrate 44 may be constructed of silicon. FIG. 9B shows the wafer in FIG. 9A after the etching process. Referring to FIG. 9B, the etched depth of substrate 44 is shown as the Si depth 46. The thickness of layer 42 after the etching process is shown as the first depth 48. In other words, the first depth 48 means the depth from the surface of the SiN layer 42 to the surface of the substrate 44. After the etching process, the width of the interface between the SiN layer 42 and the substrate 44 is shown as the first neck 50. The width of the etched bottom portion of the etched substrate 44 is shown as the bottom length 52, as shown in FIG. 9B. Obviously, if the etching of the edge portions of the wafer 20 is averaged, the above-mentioned data taken by every etching process under the same condition will not change too much. Referring to FIG. 10, some testing data is described in a table. The above-mentioned table comprises 15 testing data. In each testing, thirteen portions separated by each other in equidistance are taken from the edge of the wafer. The data of each the thirteen portions, including the thickness of the layer 40, the first depth, the first neck, and the bottom length, are measured, and each average of the above-mentioned data is obtained and shown in FIG. 10. Excluding the unit of the thickness of the layer 40 shown in angstrom, the units in the other data is shown in micrometer (em). In the last three rows in FIG. 10, each average from the fifteen testing results is described in the “Average” row. Each standard deviation of the fifteen testing results is shown in the “Standard Deviation” row. The “General Deviation” row shows each range of inaccuracies from the fifteen testing results, without employing the wafer center calibrator of this embodiment. According to the table, it is obvious that the reaction result of a wafer becomes more uniform by employing the wafer center calibrator of this embodiment. Furthermore, from the data of the Average and the Standard Deviation, the results with employing the wafer center calibrator are very close. Therefore, the wafer center calibrator of this invention can be easily operated, and the inaccuracy of the focus ring due to the mental reasons can be efficiently prevented.

Besides employing in an etching chamber, the wafer center calibrator according to this invention also can be used in other chambers. For example, in one case of this invention, the wafer center calibrator can be employed in a depositing chamber, such as a chamber for plasma enhanced chemical vapor deposition, for calibrating the focus ring in the above-mentioned chamber.

Although specific embodiments have been illustrated and described, it will be obvious to those skilled in the art that various modifications may be made without departing from what is intended, but not to be limited solely by the appended claims.

What is claimed is:

1. A calibrator for calibrating a fabricating inaccuracy of a focus ring in a chamber, comprising:
a main part; and
a art part disposed on one side of said main part, wherein said art part is suitable for a gap between a electrostatic chuck and the focus ring in said chamber, after rotating the calibrator, the gap between said electrostatic chuck and said focus ring becomes uniform.

2. The calibrator according to claim 1, wherein said chamber is an etching chamber.

3. The calibrator according to claim 1, wherein said chamber is a depositing chamber.

4. The calibrator according to claim 1, wherein said art part is curve-shaped, and the curvature radius of said art part is suitable to said focus ring.

5. The calibrator according to claim 1, wherein said calibrator comprises a pair of said art part.

6. The calibrator according to claim 5, wherein the sum of the arc of said art parts is larger than one half circumference of said gap.

7. The calibrator according to claim 1, wherein said art part is consisted of engineering plastics.

8. The calibrator according to claim 1, further comprising a handle on another side of said main part.

9. The calibrator according to claim 1, wherein said main part is a turtleback-shaped quadrangle, wherein said turtleback-shaped quadrangle comprises one pair of parallel side portions and two equal arcs.

10. A method for calibrating a electrostatic chuck and a focus ring into concentric circles in a chamber, comprising:
providing a calibrator comprising a main part and a art part, wherein said art part is on one side of said main part; and
disposing said calibrator on said electrostatic chuck and said focus ring, and the art parts disposed into a gap between said electrostatic chuck and said focus ring, when rotating said calibrator, said gap becoming uniform.

11. The method according to claim 10, wherein said chamber is an etching chamber.

12. The method according to claim 10, wherein said chamber is a depositing chamber.

13. The method according to claim 10, wherein said art part is a curve shape, and the curvature radius of said art part is suitable to said focus ring.

14. The method according to claim 10, wherein said calibrator comprises a pair of said art parts.

15. The method according to claim 14, wherein the sum of the arc of said art parts is larger than one half circumference of said gap.

16. The method according to claim 10, wherein said art part is consisted of engineering plastics.

17. The method according to claim 10, further comprising a handle on another side of said main part.

18. The method according to claim 10, wherein said main part is a turtleback-shaped quadrangle, wherein said turtleback-shaped quadrangle comprises one pair of parallel side portions and two equal arcs.
